(19) United States
(12) Patent Application Publication
(10) Pub. No.: US 2025/0300613 A1
(43) Pub. Date: Sep. 25, 2025

(54) PUSH-PULL AMPLIFIER WITH FEEDBACK CANCELLATION

(71) Applicant: AmpliTech Group Microwave Design Center (AGMDC), Plano, TX (US)

(72) Inventors: James Mason Carroll, Allen, TX (US); Bumjin Kim, Frisco, TX (US)

(73) Assignee: AmpliTech Group Microwave Design Center (AGMDC), Plano, TX (US)

(21) Appl. No.: 18/616,041

(22) Filed: Mar. 25, 2024

(51) Int. Cl. H03F 3/26; H03F 1/56; H03F 3/30; H03F 3/45

(52) U.S. Cl. CPC H03F 3/265; H03F 1/56; H03F 3/3001; H03F 3/45179; H03F 2200/318

(57) ABSTRACT

The example embodiments are directed to a push-pull amplifier embedded with cross-coupled transistor feedback cancellation. In one example, the amplifier may include a first load, a second load, a circuit comprising first and second field effect transistors (FETs) that are electrically coupled to each other and that are electrically coupled to the first load and the second load, and a feedback cancellation circuit that interconnects the first and second FETs and comprises coupling capacitors configured to increase gain, circuit stability, and Power Added Efficiency (PAE) from the first and second FETs.

### BACKGROUND

A push-pull amplifier, commonly referred to as a differential amplifier, is a type of electronic circuit that uses a pair of active devices that alternately supply current to, or sink current from, a connected load. This kind of amplifier can enhance load capacity, switching speed, common-mode noise rejection, and reduce system harmonic distortion. An example of an active device is a field-effect transistor (FET) which is capable of amplifying both analog and digital signals. Push-pull amplifiers are often found in low frequency audio applications and other signal processing systems. A push-pull amplifier design is usually realized by a matched, complementary pair of transistors, with one of the transistors being used for dissipating or sinking current from the load to ground, and the other transistor being used for supplying or sourcing current to the load from a positive power supply.

### SUMMARY

One example embodiment provides a traditional apparatus that includes a first Balun (Balanced to Unbalanced matching circuit) which is used to split the input signal into two halves 180° out of phase with each other. A second Balun is used to recombine the signals to reconstruct the amplified signal at the output. A first field effect transistor (FET) is electrically or communicatively coupled to the first Balun and electrically or communicatively coupled to the second Balun via a matching circuit, a second FET that is electrically or communicatively coupled to the first FET, electrically or communicatively coupled to the first Balun, and electrically or communicatively coupled to the second Balun via a matching circuit, a first capacitor that is electrically or communicatively coupled to a gate node of the first FET and electrically or communicatively coupled to a drain node of the second FET via a second circuit, and a second capacitor that is electrically or communicatively coupled to a gate node of the second FET and to a drain node of the first FET via a third circuit.

Another example embodiment provides a first Balun, a second Balun, first and second field effect transistors (FETs) that are electrically or communicatively coupled to each other and that are electrically or communicatively coupled to the first Balun and the second Balun, and a feedback cancellation circuit that interconnects the first and second FETs and comprises coupling capacitors configured to cancel out the feedback inherent in the first and second FETs due to the transistors themselves, the particular layout of the circuitry, or coupling between parts of the amplifier circuitry of any kind.

### BRIEF DESCRIPTION OF THE DRAWINGS

FIG. 1 illustrates a traditional push-pull amplifier.

FIG. 2 illustrates a novel push-pull amplifier according to example embodiments.

FIG. 3A illustrates a traditional FET simplified electrical equivalent small signal model.

FIG. 3B illustrates a traditional layout of a FET common to all Compound Semiconductor (III-V) fabrication facilities/foundries.

FIGS. 4A-4B illustrate Integrated Circuit layout implementations common in Compound Semiconductor (III-V) fabrication for incorporating Metal-Insulator-Metal (MIM) capacitors to cancel the transistor feedback according to example embodiments.

FIGS. 5A-5B illustrate a method of improving signal stability, gain, and Power Added Efficiency (PAE) of a push-pull amplifier according to example embodiments.

FIGS. 6A-6D illustrate power, PAE, gain and K-factor measurements for a traditional single-ended implementation of a FET using an ideal balun to create a push-pull configuration.

FIGS. 7A-7D illustrate power, PAE, gain and K-factor measurements for a novel push-pull amplifier according to example embodiments.

FIG. 8 illustrates an alternate novel push-pull amplifier whereby example embodiments are configured with impedance tuning components.

### DETAILED DESCRIPTION

A push-pull configuration of the instant application is used in silicon Integrated Circuit (IC) fabrication technologies, but it is rarely used in Compound Semiconductors based on materials such as Gallium Arsenide (GaAs), Gallium Nitride (GaN), and Indium Phosphide (InP); these are referred to as III-V materials. The instant application overcomes typical compound semiconductor layout restrictions, size constraints, and difficulty of implementation leading to better performance IC components, such as Integrated Baluns, which tend to be more lossy, and which have lower overall performance compared to their single-ended counterparts.

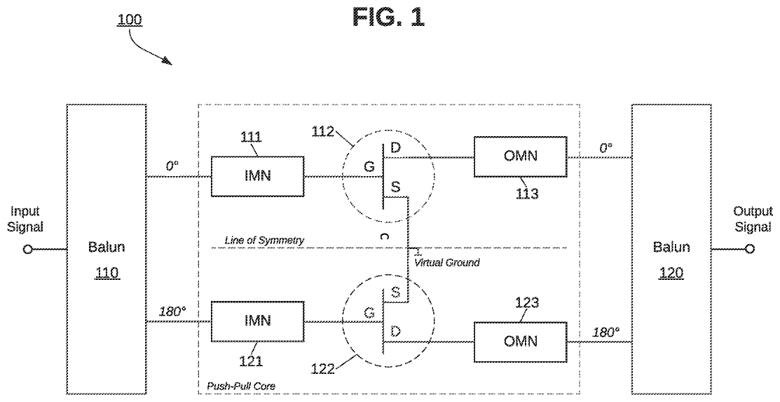

The example embodiments are directed to a feedback cancellation circuit that may be added to a push-pull amplifier such as a push-pull amplifier used for amplifying radio signals such as those transmitted over communication networks. Push-pull amplifiers typically include a pair of active devices such as a pair of field-effect transistors (FETs) which are out of phase by 180 degrees. Each FET includes a traditional design including a gate node (G), a source node (S), and a drain node (D). Meanwhile, the FETs are interconnected to each other via their respective source nodes such as shown in the example of amplifier 100 illustrated in FIG. 1 to provide a DC bias and Radio Frequency (RF) ground.

In the example of FIG. 1, the amplifier 100 includes a first transistor cell which includes an Input Matching Network (IMN) 111 that is electrically or communicatively coupled between a Balun 110 and a gate node of a field-effect-transistor (FET) 112. The first transistor cell further includes an Output Matching Network (OMN) 113 which is electrically or communicatively coupled to a drain node of the FET 112 and another Balun 120.

In FIG. 1, the amplifier 100 also includes a second transistor cell that is 180° out of phase with a phase the first transistor cell and includes a IMN 121 that is electrically or communicatively coupled to the Balun 110 and a second FET 122 which is the same as the FET 112. Likewise, the second transistor includes an OMN 123 that is electrically or communicatively coupled to a drain node of the FET 122 and the other Balun 120. Here, the difference in phase is generated by Balun 110 so that the FETs 112 and 122 which are 180° out of phase with each other. Balun 110 and a Balun 120 are used in this example to generate and recombine the out of phase signals in the push-pull amplifier core. It should be appreciated that this embodiment pertains to the push-pull core, and it also applies to inherent differential circuits if those signals are supplied by other external circuitry to the push-pull core other than Baluns.

Over time, the source nodes of the FETs 112 and 122 may experience noise. For example, inductance may be caused at the source node from a connection between metal traces on top of the FETs 112 and 122 and a ground bottom (shown in latter figures). This inductance/noise can produce feedback in the signal, causing the circuit to become unstable, and resulting in an unwanted oscillation of the transistors.

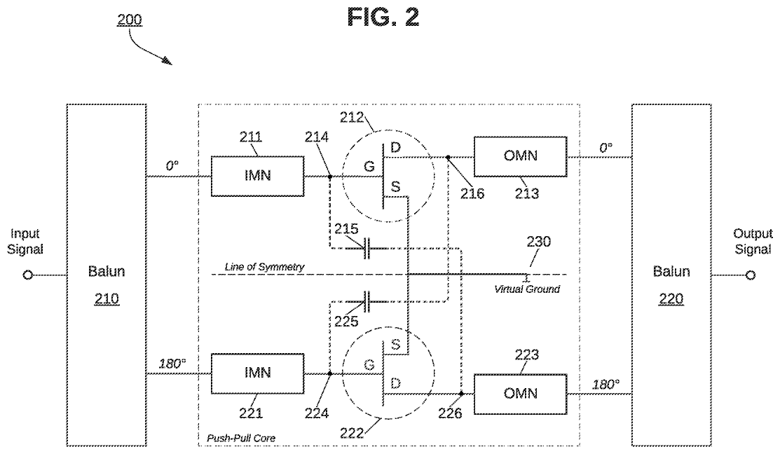

Referring to FIG. 2, the push-pull amplifier 200 includes similar components as the amplifier 100 shown in FIG. 1. For example, the push-pull amplifier also includes two transistor cells that are out of phase by 180° and similar components. However, this example also includes the cross-coupled feedback cancellation circuit that is shown with dotted lines.

In the example of FIG. 2, the first transistor cell includes the IMN 211 and the OMN 213. In this example, the IMN 211 is electrically or communicatively coupled to the Balun 210 and a gate node 214 of a field-effect transistor (FET) 212. Meanwhile, the OMN 213 is electrically or communicatively coupled to a drain node 216 of the FET 212 and the other Balun 220. The push-pull amplifier 200 also includes a second transistor cell that includes the IMN 221 and the OMN 223. Here, the IMN 221 is electrically or communicatively coupled to the Balun 210 and a gate node 224 of a FET 222. Meanwhile, the OMN 223 is electrically or communicatively coupled to a drain node 226 of the FET 222 and the other Balun 220. Inside the push-pull core, the input signal is being amplified differentially with a perfect virtual Radio Frequency (RF) ground 230 between the source connection points of the FET 212 and FET 222. The purpose of the IMN and OMN circuitry are to provide impedance match in the circuit to maximize the signal transfer from point-to-point in the circuitry. The matching networks and Baluns may or may not be combined into one network anywhere in this push-pull embodiment.

According to various embodiments, a feedback cancellation circuit is provided which interconnects the first transistor cell and the second transistor cell to cancel the transistor feedback inherent in the circuitry which negatively impacts many of the amplifier performance metrics such as gain and Power Added Efficiency (PAE). Here, the first coupling capacitor 215 is electrically or communicatively coupled to the gate node 214 of the FET 212 and the drain node 226 of the FET 222. Meanwhile, a second coupling capacitor 225 is electrically or communicatively coupled to the gate node 224 of the FET 222 and the drain node 216 of the FET 212. The embodiment of the cancelation coupling can be as simple as a single capacitor or it may be a more complex circuit coupling network to enhance performance such as, but not limited to, bandwidth improvement, harmonic suppression, and harmonic tuning for higher performance of the push-pull core.

In the example of FIG. 2, an output from the FET 222 is fed from the drain node 226 to an input (the source node 214) of the FET 212. Likewise, an output of the FET 212 is fed from the drain node 216 to an input (source node 224) of the FET 222. In this case, some of the signal that is output from the FET 222 and input to the FET 212 via a coupling capacitor 215 can be used to cancel feedback capacitance caused by the FET 222. In addition, some of the signal that is output from the FET 212 and input to the FET 222 via a coupling capacitor 225 can be used to cancel feedback capacitance caused by the FET 212. This new topology has tremendous benefits to PAE and Amplifier Gain.

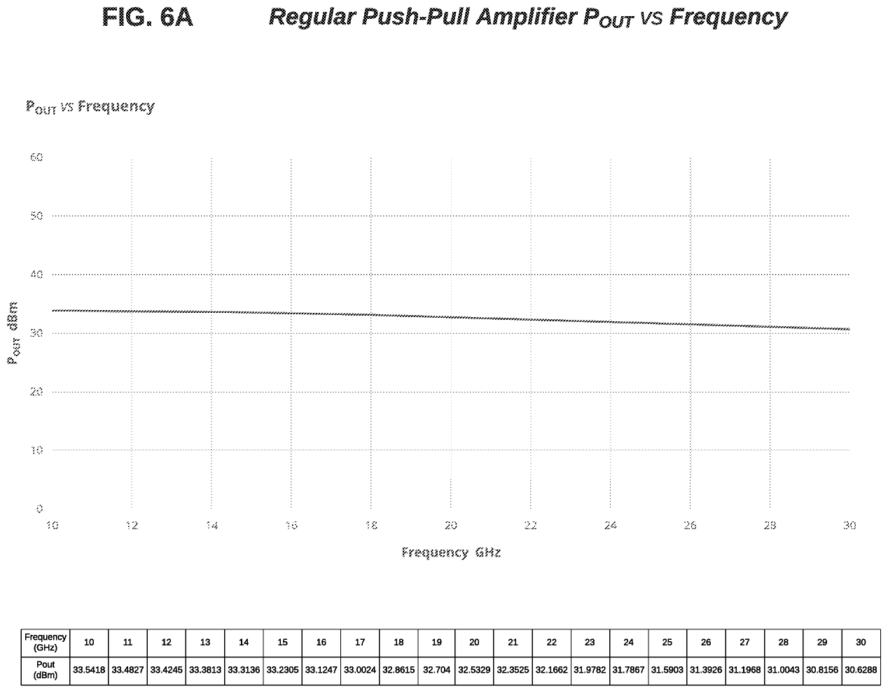

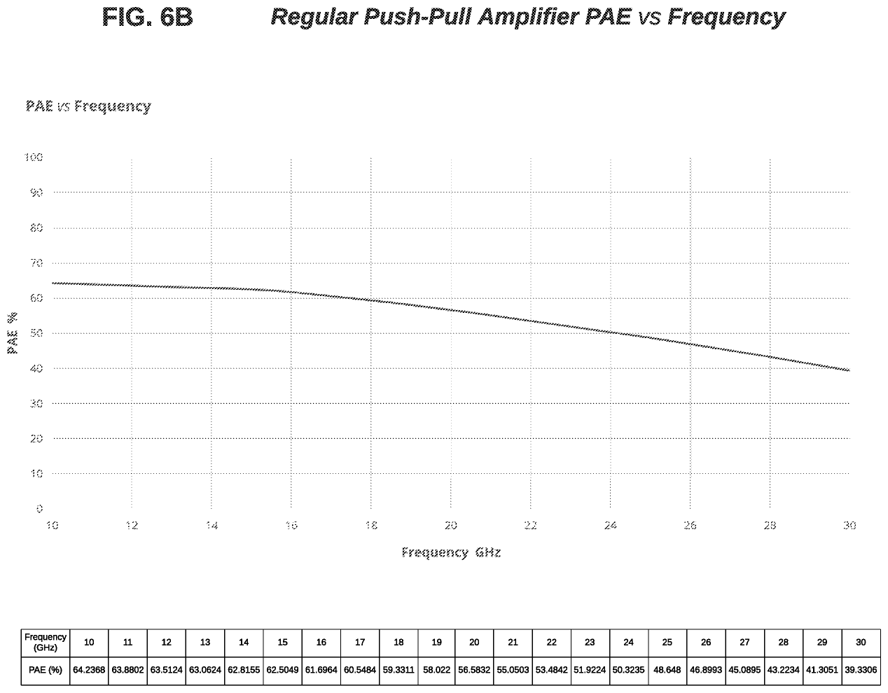

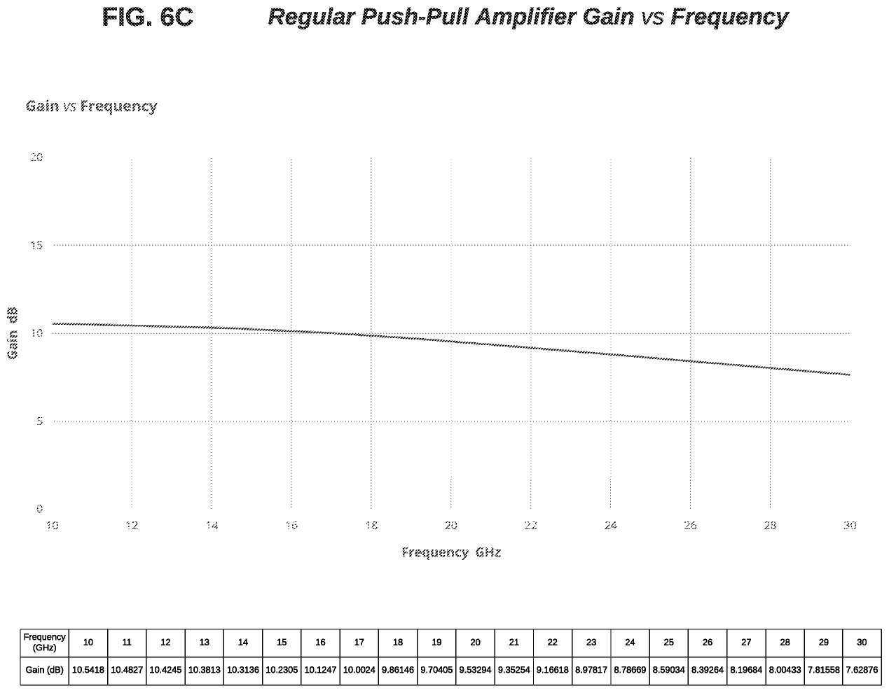

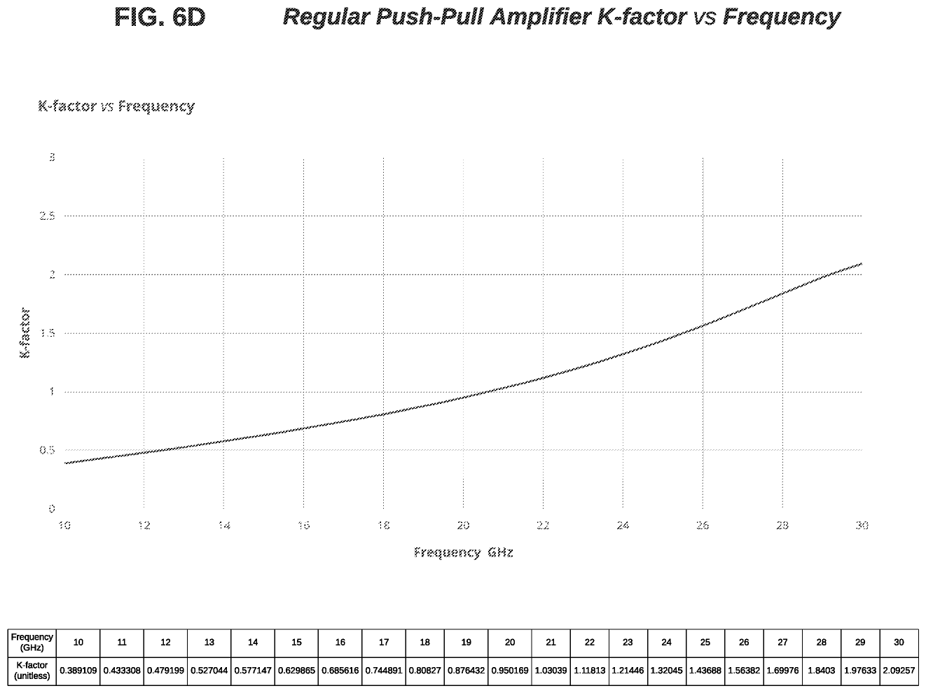

In some embodiments, the virtual ground in between the transistor cells makes the amplifier immune to any noise in the ground or common node; referred to as having high common mode rejection. Cross-coupling in the push-pull core of 200 results in higher in-band gain from the virtual RF ground inherent in the differential signal which, in turn, leads to inherently higher gain and PAE of the amplifier as described in FIG. 6.

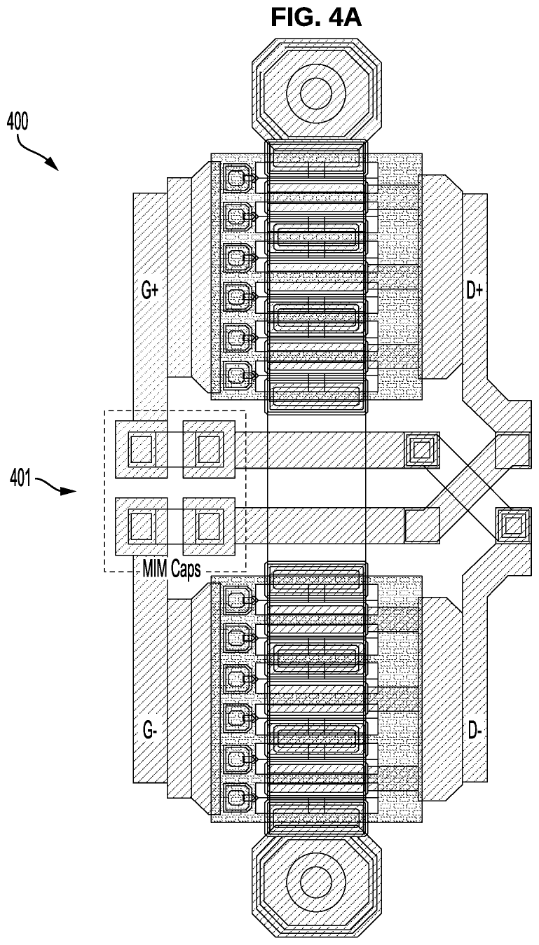

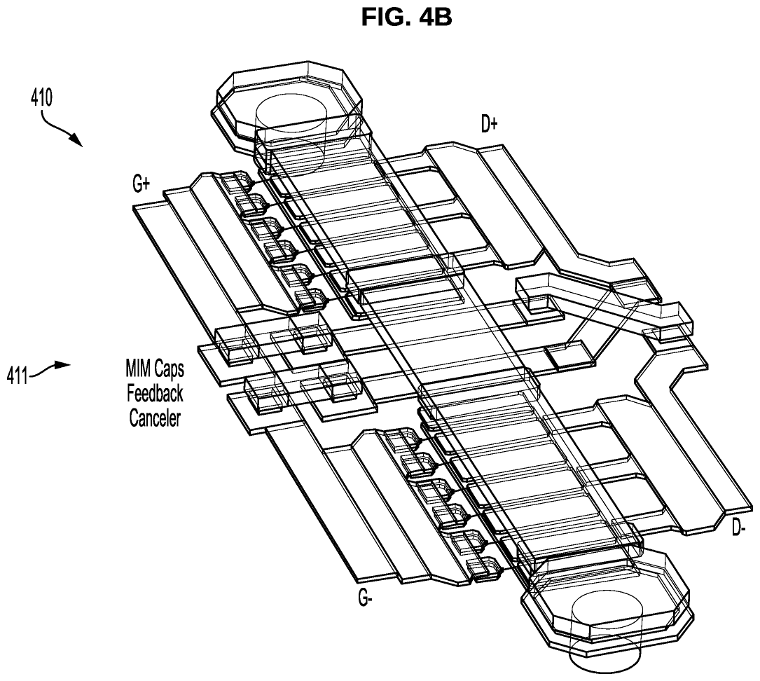

By crossing the external gate-to-drain capacitor to opposite transistors, the transistor's parasitic internal feedback capacitance (referred to as, C_{gd}) can be cancelled out or neutralized, which eliminates the feedback element inherent to the transistor. This makes the transistor to be unconditionally stable, and it simplifies the design of amplifiers to a much higher stability margin. Feedback cancellation in the push-pull core 200 also results in less need for external stabilization outside of the amplifier (which simplifies circuits), easier impedance matching across the signal inputs, higher Gain and higher PAE. In the examples above, the coupling capacitors 215 and 225 can be neutralization capacitors that are generated using standard MIM (Metal-Insulator-Metal) capacitors and metal trace routing which adhere to existing design rules of fabrication and do not require any special or additional fabrication processes to realize (reference FIGS. 4A-4B).

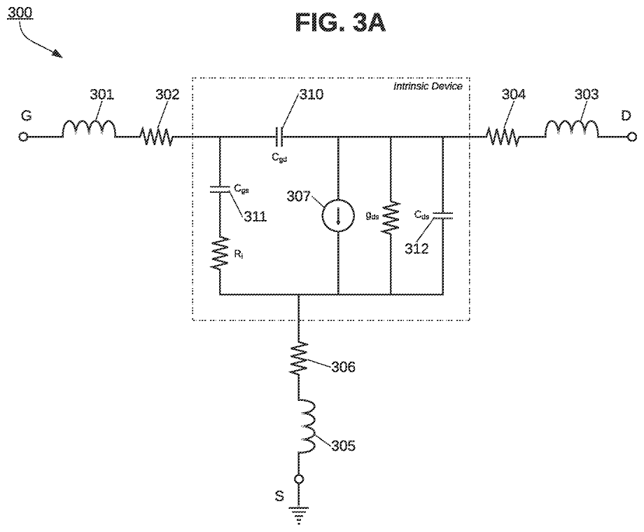

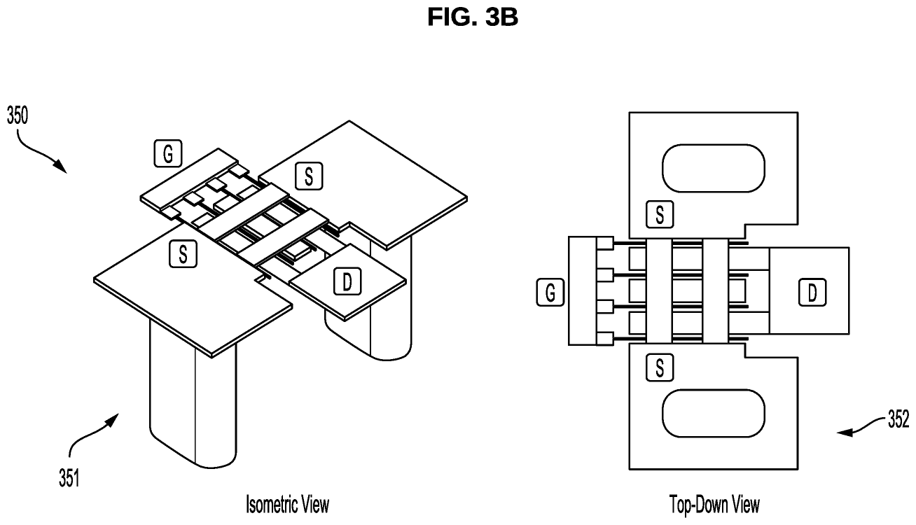

FIG. 3A illustrates a traditional simplified equivalent electrical FET model 300. The components 301, 303, and 305 represent inductances and electrical length getting into the core transistor. Components 302, 304, and 306 represent the resistive losses the signal experiences in the transistor. Component 311 represents the input capacitance of the transistor while 312 the output capacitance. Component 307 is the voltage-controlled current source that amplifies the transistor input signal based on the voltage experience in across the input capacitance 311. Component 310 represents the feedback capacitance that this patent cancels with the push-pull implementation. One skilled in the art will refer to Component 310 as parasitic capacitance, and it reduces circuit stability, gain, and PAE of the amplification.

FIG. 3B illustrates a traditional layout 350 of a FET common to all Compound Semiconductor (III-V) fabrication facilities/foundries. Two layout views are depicted; an isometric view 351 and a top-down view 352.

FIGS. 4A-4B illustrate IC layout implementations 400 and 410 that embody ideas in this patent by demonstrating how the feedback cancellation can be realized according to the strict layout rules common at all Compound Semiconductor (III-V) fabrication facilities/foundries. Metal-Insulator-Metal (MIM) capacitors 401 and 411 and interconnected trace layers form the cross-coupled capacitances to cancel the transistor feedback.

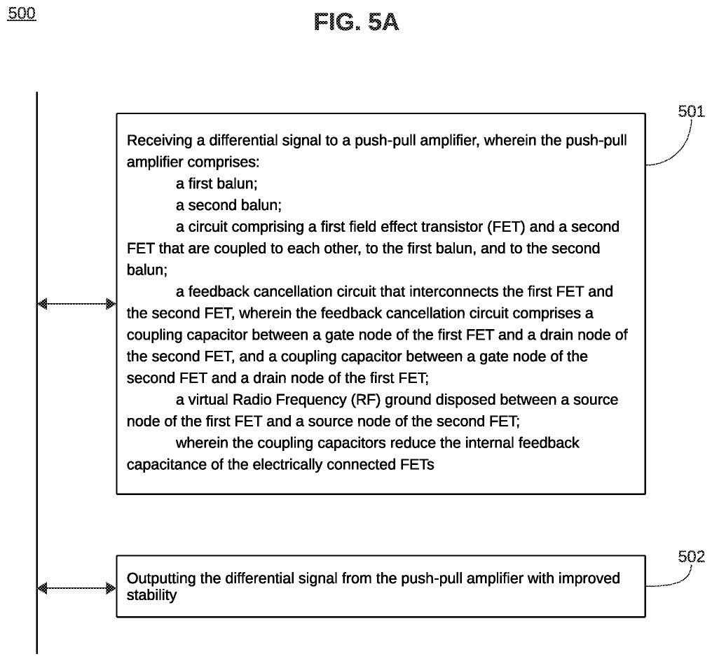

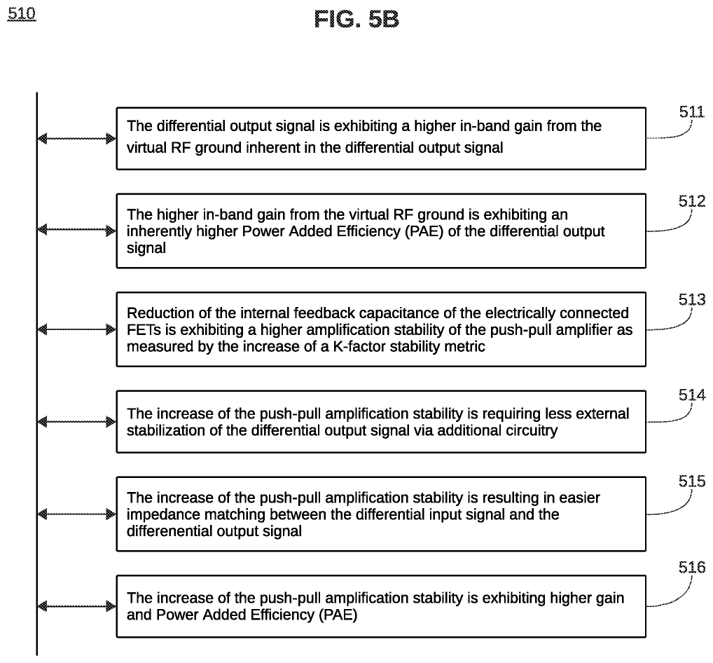

FIG. 5A illustrates a method 500 of receiving a differential signal step 501 into a differential amplifier that includes a push-pull core as described by apparatus 200 in FIG. 2. In step 502, the method outputs a differential signal with improved stability.

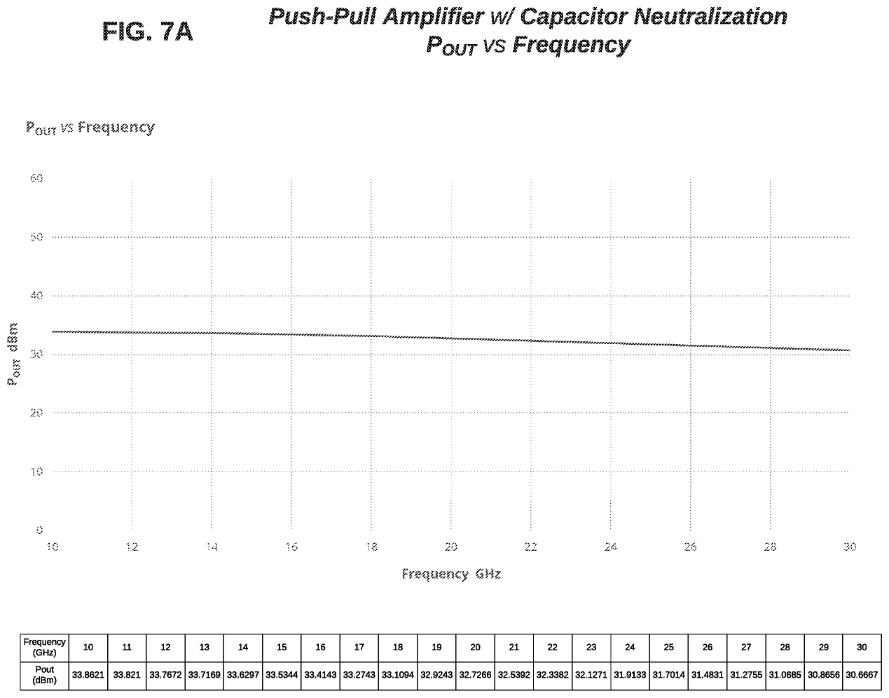

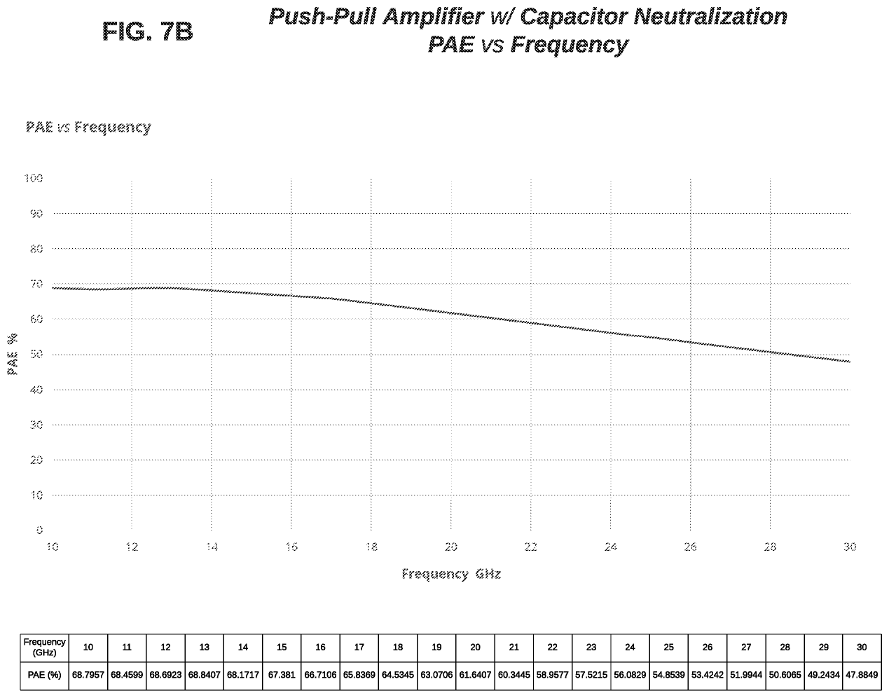

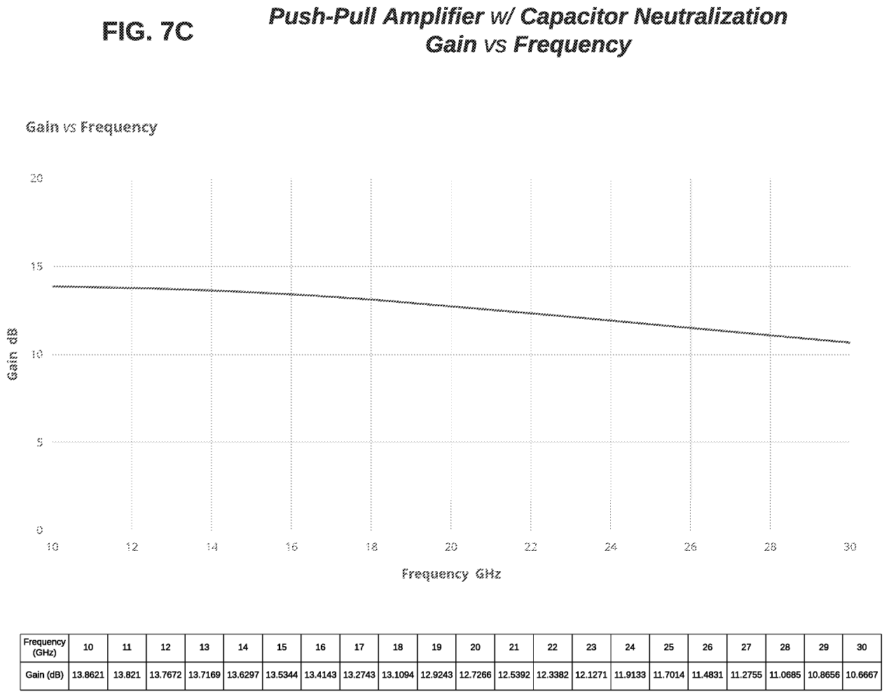

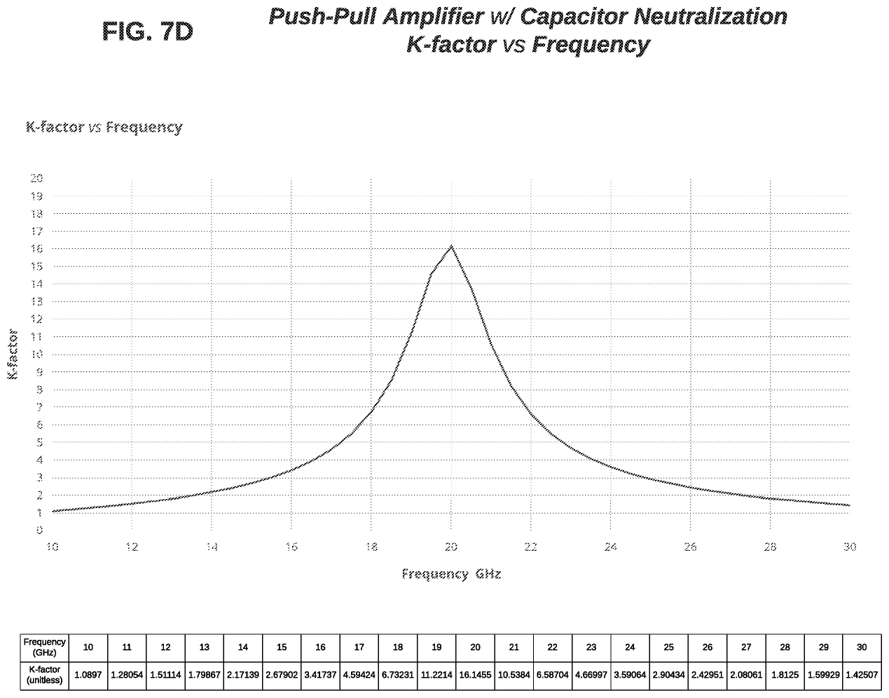

FIG. 5B illustrates a method 510 of quantifying the stability improvements realized by method 500. Referring to FIG. 5B, in step 511, the differential output signal exhibits a higher in-band gain from the virtual RF ground inherent in the push-pull core of 200. In step 512, the higher in-band gain of 511 leads to higher measured PAE as shown in FIGS. 7B and 7C. In step 513, the reduction of internal feedback capacitance of the electrically or communicatively coupled FETs of the push-pull core of 200 exhibits higher amplification stability of the differential output signal as measured by an increase in K-factor and as shown in FIG. 7D. In step 514, the higher amplification stability of step 513 requires less external stabilization of the differential output signal via the addition of circuitry outside the push-pull core of 200. In step 515, the higher amplification stability of step 513 results in easier impedance matching between the differential input and output signals across the push-pull amplifier 200. In step 516, the higher amplification stability of step 513 increases the gain and PAE of the differential output signal as shown in FIGS. 7B and 7C.

FIGS. 6A-6D illustrate various IC design block performance measurements for a traditional push-pull amplifier that combines a single-ended FET and an ideal balun to create a typical push-pull configuration. Specifically, FIG. 6A summarizes power output (Pout) measurements over a frequency range of 10 to 30 GHz, which represent how much RF power the amplifier can produce; FIG. 6B displays PAE measurements, which represent the efficiency of RF power production as a percentage of the DC power required to drive the amplifier; FIG. 6C illustrates the large signal gain measurements of the amplifier; and FIG. 6D describes the K-factor stability measurements, where values greater than 1 represent an unconditionally stable amplifier for the corresponding input frequency.

FIGS. 7A-7D illustrate various IC design block performance measurements for a novel push-pull amplifier configured with neutralization capacitors according to example embodiments. Specifically, FIG. 7A summarizes power output (Pout) measurements over a frequency range of 10 to 30 GHz, which represent how much RF power the novel amplifier can produce; FIG. 6B displays PAE measurements, which represent the efficiency of RF power production as a percentage of the DC power required to drive the novel amplifier; FIG. 6C illustrates the large signal gain measurements of the novel amplifier; and FIG. 6D describes the K-factor stability measurements, where values greater than 1 represent an unconditionally stable amplifier for the corresponding input frequency. Comparing FIGS. 6A-6D with FIGS. 7A-7D, one skilled in the art will recognize the novel amplifier to be unconditionally stable at any input frequency with improved gain and PAE.

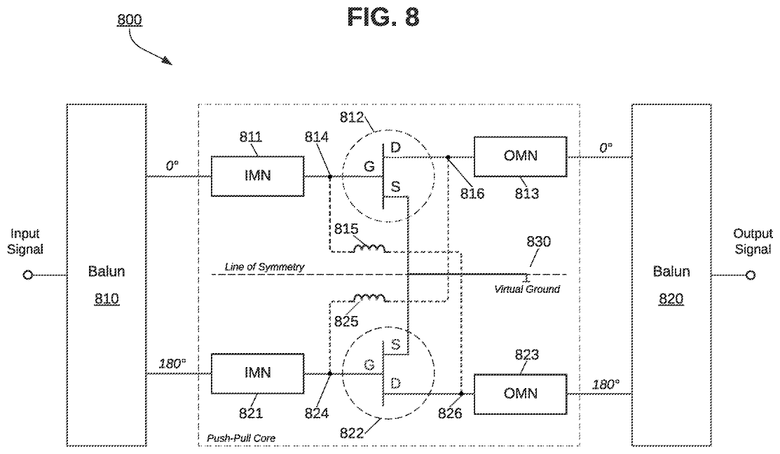

FIG. 8 illustrates an alternate embodiment of the novel push-pull amplifier 200. Referring to FIG. 8, a push-pull amplifier 800 substitutes the cross-coupled feedback cancellation capacitors with arbitrary impedance components 815 and 825 which are shown cross-connected with dotted lines.

In the example of FIG. 8, the first transistor cell includes the IMN 811 and the OMN 813. In this example, the IMN 811 is electrically or communicatively coupled to the Balun 810 and a gate node 814 of a field-effect transistor (FET) 812. Meanwhile, the OMN 813 is electrically or communicatively coupled to a drain node 816 of the FET 812 and the other Balun 820. The push-pull amplifier 800 also includes a second transistor cell that includes the IMN 821 and the OMN 823. Here, the IMN 821 is electrically or communicatively coupled to the Balun 810 and a gate node 824 of a FET 822. Meanwhile, the OMN 823 is electrically or communicatively coupled to a drain node 826 of the FET 822 and the other Balun 820. Inside the push-pull core, the input signal is being amplified differentially with a perfect virtual Radio Frequency (RF) ground 830 between the source connection points of the FET 812 and FET 822. The purpose of the IMN and OMN circuitry are to provide impedance match in the circuit to maximize the signal transfer from point-to-point in the circuitry. The matching networks and Baluns may or may not be combined into one network anywhere in this push-pull embodiment.

According to the alternate embodiment 800, an impedance circuit is provided which interconnects the first transistor cell and the second transistor cell to facilitate harmonics tuning of the circuitry between each half of the push-pull core; thus, performance characteristics of the amplifier, such as PAE, are improved. Here, the first impedance components 215 are electrically or communicatively coupled to the gate node 214 of the FET 212 and the drain node 226 of the FET 222. Meanwhile, a second impedance components 225 are electrically or communicatively coupled to the gate node 224 of the FET 222 and the drain node 216 of the FET 212. The embodiment of the coupling impedance components can be as simple as a single inductor, or it may be a more complex tuning circuit designed to enhance harmonic stability of the amplifier and to increase performance of the push-pull core.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent.

While preferred embodiments of the present application have been described, it is to be understood that the embodiments described are illustrative only and the scope of the application is to be defined solely by the appended claims when considered with a full range of equivalents and modifications (e.g., protocols, hardware devices, software platforms etc.) thereto.

What is claimed is:

1. An apparatus, comprising:
a first balun;
a second balun;
a first Field Effect Transistor (FET) that is coupled the first balun and the second balun;
a second FET that is coupled to the first balun, and the second balun;
wherein the first FET and the second FET are coupled;
a first capacitor that is coupled to a gate node of the first FET and coupled to a drain node of the second FET; and
a second capacitor that is coupled to a gate node of the second FET and to a drain node of the first FET.

2. The apparatus of claim 1, wherein the first FET and the second FET comprise a gate node, a drain node, and a source node, wherein the first and the second FET are interconnected via the source node of the first FET the source node of the second FET.

3. The apparatus of claim 1, wherein the first capacitor is configured to cancel inherent signal feedback between the gate node and the drain node of the first FET, and the second capacitor is configured to cancel inherent signal feedback between the gate node and the drain node of the second FET.

4. The apparatus of claim 1 comprising a virtual ground disposed between the source node of the first FET and the source node of the second FET.

5. The apparatus of claim 1 comprising a first input matching network (IMN) that is coupled to the first balun and the gate node of the first FET and a second IMN that is coupled to the first balun and the gate node of the second FET.

6. The apparatus of claim 1, wherein an input signal of the first FET is inversely phase balanced from an input signal of the second FET.

7. The apparatus of claim 1 comprising a first output matching network (OMN) that is coupled to the drain node of the first FET and the second balun, and a second OMN that is coupled to the drain node of the second FET and the second balun.

8. A method, comprising:
receiving a differential signal to a push-pull amplifier, wherein the push-pull amplifier comprises:
a first balun;
a second balun;
a circuit comprising a first field effect transistor (FET) and a second FET that are coupled to each other, to the first balun, and to the second balun;
a feedback cancellation circuit that interconnects the first FET and the second FET, wherein the feedback cancellation circuit comprises a coupling capacitor between a gate node of the first FET and a drain node of the second FET, and a coupling capacitor between a gate node of the second FET and a drain node of the first FET;
a virtual Radio Frequency (RF) ground disposed between a source node of the first FET and a source node of the second FET;
wherein the coupling capacitors reduce the internal feedback capacitance of the electrically connected FETs; and
outputting the differential signal from the push-pull amplifier with improved stability.

9. The method of claim 8, wherein the differential output signal is exhibiting a higher in-band gain from the virtual RF ground inherent in the differential output signal.

10. The method of claim 9, wherein the higher in-band gain from the virtual RF ground is exhibiting an inherently higher Power Added Efficiency (PAE) of the differential output signal.

11. The method of claim 8, wherein reduction of the internal feedback capacitance of the electrically connected FETs is exhibiting a higher amplification stability of the push-pull amplifier as measured by the increase of a K-factor stability metric.

12. The method of claim 11, wherein the increase of the push-pull amplification stability is requiring less external stabilization of the differential output signal via additional circuitry.

13. The method of claim 11, wherein the increase of the push-pull amplification stability is resulting in easier impedance matching between the differential input signal and the differential output signal.

14. The method of claim 11, wherein the increase of the push-pull amplification stability is exhibiting higher gain and Power Added Efficiency (PAE).
